(19) United States
(12) Patent Application Publication
(10) Pub. No.: US 2012/0241755 A1
(43) Pub. Date: Sep. 27, 2012

(54) METHOD FOR REDUCING INTERNAL MECHANICAL STRESSES IN A SEMICONDUCTOR STRUCTURE AND A LOW MECHANICAL STRESS SEMICONDUCTOR STRUCTURE

(76) Inventors: Alexey Romanov, St. Petersburg (RU); Maxim A. Odnoblyudov, St. Petersburg (RU); Vladislav E. Bougrov, St. Petersburg (RU)

(21) Appl. No.: 13/395,496

(22) PCT Filed: Sep. 9, 2010
(86) PCT No.: PCT/FI2010/050696

§ 371 Date: May 25, 2012

(30) Foreign Application Priority Data
Sep. 10, 2009 (FI) 20095937

(51) Int. Cl. H01L 29/20; H01L 21/20

(52) U.S. Cl. 257/76; 438/478; 257/E29.089; 257/E21.09

(57) ABSTRACT

A semiconductor structure with low mechanical stresses, formed of nitrides of group III metals on a (0001) oriented foreign substrate (1) and a method for reducing internal mechanical stresses in a semiconductor structure formed of nitrides of group III metals on a (0001) oriented foreign substrate (1). The method comprises the steps of; growing nitride on the foreign substrate (1) to form a first nitride layer (2); patterning the first nitride layer (2) by selectively removing volumes of it to a predetermined depth from the upper surface of the first nitride layer (2), for providing relaxation of mechanical stress σ in the remaining portions of the layer between the removed volumes; and growing, on the first nitride layer (2), additional nitride until a continuous second nitride layer (8) is formed, the second nitride layer (8) enclosing voids (7) from the removed volumes under the second nitride layer (8) inside the semiconductor structure.

### FIELD OF THE INVENTION

The present invention relates to a semiconductor structure formed of nitrides of group III metals with wurtzite crystal structure and grown in vapor phase on a (0001) oriented foreign substrate lattice mismatched to the materials of the semiconductor structure. The invention also relates to devices utilizing and to a method of manufacturing such a structure.

### BACKGROUND OF THE INVENTION

Due to its many advantageous properties, Gallium Nitride (GaN) in its many variations has become one of the most important semiconductor materials for optoelectronic devices like Light Emitting Diodes (LEDs) and Laser Diodes (LDs). However, unavailability of high quality, preferably stand-alone GaN templates is a well known problem in this field of modern technology. Two important factors determining the material quality are the threading dislocation (TD) density and internal mechanical stresses in the layer and the substrate. A high TD density, which typically lies in the range of 10¹⁰ cm⁻² for GaN grown by metalorganic chemical vapor deposition (MOCVD) on a sapphire substrate, affects drastically the device performance and lifetime. The stresses in turn can lead to cracking of the epitaxial GaN and/or the substrate or the device layers later grown on the GaN template. High level of stresses can also result in poor surface morphology, e.g. in high surface roughness. Additionally, internal mechanical stresses may lead to the bowing of GaN-based templates grown on foreign substrates.

Several techniques are known in the prior art for diminishing the TD density. For example, Epitaxial Layer Overgrowth (ELO or ELOG) is reported in the literature as many variations, see e.g. Gibart: “Metal organic vapor phase epitaxy of GaN and lateral overgrowth”, Reports on Progress in Physics 67 (2004) 667-715, or R. Davis et al. in U.S. Pat. No. 6,051,849. ELO techniques, however, have several drawbacks including, for example, the need for masking in the basic ELO process, decreased TD density in specific portions of the template only with remaining high TD-density areas, etc. Another method for reducing the TD-density in gallium nitride layers is a method often referred to as pendeoepitaxy. In this method trenches are formed, e.g. by etching, into the substrate and/or into another nitride epilayer, and subsequently these trenches are laterally overgrown without masking by controlling the growth direction of the gallium nitride layer by process parameters. This method is disclosed e.g. in U.S. Pat. No. 6,265,289. Pendeoepitaxy has also the problem of only being able to reduce TD density in specific portions of the epilayer only.

A totally different and one of the most efficient TD density reduction methods is disclosed in the authors' earlier patent application, publication #WO 2006/064081 A1. Said method provides a well controlled, entirely in situ method to produce GaN substrate with a TD density of less than 10⁸ cm⁻² throughout the template surface.

Much less development has been reported on the issue of internal stresses. In practice, the GaN templates with a small TD-density grown by the commonly known processes, by e.g. ELO or pendeoepitaxy, discussed above are characterized by very high internal stresses. These stresses limit the highest possible crack-free thickness achievable for the epilayers and also deteriorate the surface morphology of GaN templates. The high internal stresses in the structure can cause a substrate to crack before or during the fabrication of a device on the substrate, e.g. as a result of substrate thinning. Thus, there is a great need for a process enabling heteroepitaxial growth of GaN providing a low TD density in the GaN layer while efficiently reducing stresses in the layer, to e.g. enable a smooth surface morphology desirable for the fabrication of device structures on the layer, i.e. the GaN template.

What is said above and in the following about GaN concerns to appropriate extent also other nitrides of group III metals like AlₓGa₁₋ₓN, 0<x≦1; In_{y}Ga_{1-y}N, 0<y≦1; or BN.

### PURPOSE OF THE INVENTION

A purpose of the present invention is to reduce the problems of the prior art discussed above. Specifically, the purpose of the present invention is to provide a new type of semiconductor structure with a low level of internal mechanical stresses, a planar surface morphology preferable for epitaxial growth and a low threading dislocation (TD) density. Another purpose of the present invention is to provide a novel method for producing templates of nitrides of group III metals having relaxed subsurface mechanical stresses, planar surface morphology and a low TD density. The structures produced according to the present invention can be used as templates for epitaxial growth of device layers for e.g. power electronics or optoelectronics components. A purpose of the invention is also to provide a new type of semiconductor device comprising a semiconductor structure according to the present invention.

### SUMMARY OF THE INVENTION

The method according to the present invention is characterized by what is presented in independent claim 1.

The product according to the present invention is characterized by what is presented in independent claim 7.

The use according to the present invention is characterized by what is presented in independent claim 10 or 11.

A method for reducing internal mechanical stresses in a semiconductor structure formed of nitrides of group III metals on a (0001) oriented foreign substrate, according to the present invention comprises the steps of: growing nitride on the foreign substrate to form a first nitride layer, patterning the first nitride layer by selectively removing volumes of it to a predetermined depth from the upper surface of the first nitride layer, for providing relaxation of internal mechanical stress in the remaining portions of the layer between the removed volumes, and growing, on the first nitride layer, additional nitride until a continuous second nitride layer is formed, to produce enclosed voids from the removed volumes under the second nitride layer inside the semiconductor structure.

A semiconductor structure with low mechanical stresses formed of nitrides of group III metals on a (0001) oriented foreign substrate, according to the present invention comprises a first nitride layer on the foreign substrate, a second nitride layer on the first nitride layer, the second nitride layer enclosing intentionally induced voids under the second nitride layer inside the semiconductor structure, for reducing internal mechanical stresses in the semiconductor structure.

The method and the product according to the present invention are used to reduce internal mechanical stresses in a semiconductor structure formed of nitrides of group III metals. An additional benefit of the invention is that the relaxation of the semiconductor structure also results in a reduction of mechanical stresses in the underlying foreign substrate.

The foreign substrate should be understood as a substrate of a material different from the nitride material(s) of the semiconductor structure on the foreign substrate. The nitride of group III metals can be, as an example only, GaN, for which the most typical foreign substrate material is sapphire. The first nitride layer or the second nitride layer do not have to be homogeneous in composition, but they can be, as an example only, layered structures comprising different nitrides in themselves. The nitride layers can be formed of e.g. nitrides of group III metals having wurtzite crystal structure. The nitride layers can be grown e.g. from vapor phase by metalorganic chemical vapor deposition (MOCVD) either on a (0001) oriented foreign substrate, lattice mismatched to the semiconductor substrate materials, or on existing (0001) oriented stressed nitride layer.

The present invention provides a semiconductor structure and a method for producing a semiconductor structure which has the advantage of being highly relaxed, i.e. the structure has only very small mechanical stresses. Additional advantages which can be obtained with the present invention are a planar surface morphology and a small threading dislocation (TD) density. Planar surface morphology in this context means an essentially flat surface with negligible surface roughness.

The removed volumes form optical discontinuity interfaces within the template. When this kind of semiconductor structure is used as a substrate (as a template) of an LED, these interfaces increase the diffusion of light generated in the LED and propagating within the device due to reflections at nitride/foreign substrate and component/ambient interfaces. “Diffusion” here refers to all kind of mechanisms changing the direction of propagation of light at the interfaces, including reflection, scattering and refraction. Saying it in other words, diffusion randomly changes the propagation directions of the light rays, thus improving their probability to have a direction in which escaping from the device is possible. Consequently, the light extraction efficiency of the LED can be increased by the semiconductor structure according to the present invention.

The aforementioned advantages of the invention result from the initially flat, stressed, first nitride layer being subjected to the formation of structures with three dimensional (3D) geometries, e.g. trenches or holes. The 3D structures are formed by selectively removing volumes of the first nitride layer to a predetermined depth from the upper surface, which can be accomplished by e.g. ion-etching. The formation of the 3D structures causes the strain-stress state to become non-uniform, and the top regions of the first nitride layer, in the regions in between the removed volumes, become essentially stress-free and exhibit a lower level of mechanical stresses compared to the corresponding regions of the initial essentially two dimensional first nitride layer. Change in the stress-strain state of the first nitride layer gives also rise to shear components of stresses at the bottom of the remaining first nitride layer. The presence of such shear stresses can be an additional reason for the intensification of relaxation processes in first nitride layer after the formation of the 3D structures.

As the top regions of the first nitride layer, in the regions in between the removed volumes, become essentially stress-free the growth of the second nitride layer can be made to start from a surface being essentially stress-free or having only small stresses. Therefore growth of the second nitride layer is stable and will provide a flat surface. The exact conditions for obtaining the best results with the present invention depend on the shape and size of the 3D structures, growth regimes for the nitride layers, and the equipment used for growth and processing. These parameters will be described in more detail below.

An additional surprising advantage of the invention is that the enclosed voids in the semiconductor structure under the second nitride layer efficiently enhance light extraction from device structures grown on the semiconductor structure.

According to one embodiment of the present invention patterning the first nitride layer comprises removing volumes of the first nitride layer, such that the depth H of the removed volumes, a characteristic diameter D of the removed volumes, and the spacing L between adjacent removed volumes satisfy the condition H/(L−D)>0.2, more preferably the condition H/(L−D)>0.4, and most preferably the condition H/(L−D)>0.6. When the geometry of the patterning of the first nitride layer satisfies these conditions, the remaining portions of the first nitride layer in between the removed volumes exhibit a high level of relaxation of internal mechanical stresses. Furthermore the relaxation occurs in large regions of the remaining first nitride layer in between the removed volumes, which provides a large surface area of relaxed material for the growth of the second nitride layer to start on.

According to another embodiment of the present invention patterning the first nitride layer comprises removing volumes of the first nitride layer such that the cross-section of the removed volumes, along a surface parallel to the surface of the foreign substrate, is shaped as a hexagon.

In yet another embodiment of the invention orientation of the faces of the removed volumes essentially coincide with the low index crystallographic planes of a wurtzite crystal structure. In this embodiment the orientation of faces of e.g. hexagonal prisms defining the removed volumes coincide with e.g. low index m- or a-planes of the first nitride layer. This further stimulates relaxation of the internal mechanical stresses of the first nitride layer.

According to yet another embodiment of the present invention the cross-section of the removed volumes, along a surface parallel to the surface of the foreign substrate, has a characteristic diameter D of at least 2.0 micrometers, the spacing L between adjacent removed volumes is less than 10.0 micrometers, and the depth H of the removed volumes is more than 3.0 micrometers.

To further stimulate stress relaxation in the upper parts of the first nitride layer the first nitride layer is, in some embodiments of the invention, patterned to a specific shape. The geometry of the removed volume and the relative volume of the corresponding removed material have been found to strongly affect the surprising stress relaxation in the upper parts of the first nitride layer. It has been found that a removed material volume having a hexagon shaped cross section and an optimal characteristic diameter D which is related to the predetermined depth H via D˜H, efficiently relaxes stresses in the upper parts of the first nitride layer.

According to one embodiment of the present invention, growing, on the first nitride layer, additional nitride, comprises growing the additional nitride such that the growth rate decreases gradually towards the bottom of the removed volumes, for enclosing the voids from the removed volumes such that the characteristic cross-sectional diameter of the voids, along a surface parallel to the surface of the foreign substrate, increases as a function of depth.

According to another embodiment of the present invention the cross-section of the voids, along a surface parallel to the surface of the foreign substrate, has a characteristic diameter DV of at least 2.0 micrometers, and the lateral spacing LV between adjacent voids is less than 10.0 micrometers. According to yet another embodiment of the present invention the characteristic cross-sectional diameter of the voids, along a surface parallel to the surface of the foreign substrate, increases as a function of depth.

With a suitable choice of process parameters, which will be discussed below in more detail, the second nitride layer can be made to grow such that voids whose cross-sectional diameter, in the plane of the substrate or of the nitride layers, increases as a function of depth from the growth surface, will be formed from the removed volumes under the second nitride layer. Enclosed voids of this shape can efficiently reduce the TD density in the second nitride layer, while still enabling the second nitride layer to grow with only small or negligible internal mechanical stresses. This “pyramidal” or “triangular” shape of the voids additionally enhances light extraction from a light emitting device (e.g. an LED) fabricated onto the second nitride layer, which increases the external quantum efficiency of the light emitting device.

The embodiments of the invention described hereinbefore may be used in any combination with each other. Several of the embodiments may be combined together to form a further embodiment of the invention. A method, a product or a use, to which the invention is related, may comprise at least one of the embodiments of the invention described hereinbefore.

### BRIEF DESCRIPTION OF THE DRAWINGS

In the following, the present invention will be described in more detail with exemplary embodiments by referring to the accompanying figures, in which

FIG. 1 schematically shows the steps in the process flow of a method according to one embodiment of the present invention,

FIG. 2 shows an example of calculated elastic strains which are proportional to internal mechanical stresses, as a function of aspect ratio M/2h in posts formed by selectively removing part of a GaN layer grown on a sapphire substrate,

FIG. 3a schematically presents the definition of a characteristic diameter D of the removed volumes, the lateral spacing L of adjacent removed volumes, and the depth H of the removed volumes, as a side-view cross section of a structure according to one embodiment of the present invention, after patterning of the first nitride layer,

FIG. 3b schematically presents the definition of a characteristic diameter D of the removed volumes, and the lateral spacing L of adjacent removed volumes, as a plane-view cross section of a structure according to one embodiment of the present invention, after triangular patterning of the first nitride layer,

FIG. 3c schematically presents the definition of a characteristic diameter D of the removed volumes, and the lateral spacing L of adjacent removed volumes, as a plane-view cross section of a structure according to another embodiment of the present invention, after square patterning of the first nitride layer,

FIG. 4 schematically presents the definition of a characteristic diameter DV of the voids, and the lateral spacing LV of adjacent voids, as a side-view cross section of a structure according to one embodiment of the present invention, after overgrowth of the first nitride layer with the second nitride layer,

FIG. 5a and FIG. 5b show schematically, in more detail, the formation of enclosed voids in a method according to one embodiment of the present invention,

FIG. 6a shows schematically, in more detail, possible line directions of threading dislocations in the remaining material volumes, after patterning the first nitride layer and initial growth of the second nitride layer according to one embodiment of the present invention,

FIG. 6b shows schematically, in more detail, possible line directions of threading dislocations in a semiconductor structure according to one embodiment of the present invention, after growing the second nitride layer,

FIG. 7 shows schematically the effect of cavities, formed within a nitride template according to one embodiment of the present invention, on threading dislocations and on internal mechanical stresses in a semiconductor structure according to one embodiment of the present invention,

FIG. 8 is a scanning electron microscope (SEM) image of ICP-RIE etched hexagonal removed volumes of the first nitride layer, according to one embodiment of the present invention,

FIG. 9 is an SEM image of a cross section of a template grown according to one embodiment of the present invention,

FIG. 10 is an SEM image of a cross-section of a semiconductor structure according to one embodiment of the present invention,

### DETAILED DESCRIPTION OF THE INVENTION

The prior-art research has showed formation of large tensile elastic strains and corresponding mechanical stresses at the growth stage of III-nitride layers grown in (0001) orientation on foreign substrates. It is well known that there are two main reasons for stress generation in heteroepitaxially grown GaN. Firstly, tensile stresses arise at the early growth stage mainly due to coalescence of 3D islands in Volmer-Weber and Stanski-Krastanov growth modes. Secondly, thermal mismatch, i.e. the difference in thermal expansion coefficients between e.g. an epitaxial GaN layer and the foreign substrate (e.g. sapphire) causes tensile stresses in the substrate when the whole structure is cooled down after the growth process, which can be carried out in e.g. an MOCVD reactor. In the case of the growth of AlₓGa₁₋ₓN, 0<x≦1 layers on GaN templates lattice mismatch between the layer and the substrate results in the generation of additional tensile stresses in the layer at the growth temperatures. In the case of (0001) oriented growth of III-nitrides, especially with layers of low threading dislocation density where relaxation does not efficiently occur through the motion of TDs and generation of misfit dislocations (MDs), the possible mechanisms of stress relaxation include the formation of a rough surface and cracking of the nitride layers and/or the substrate.

The thicker is the epitaxial GaN the more elastic energy is involved in the stressed materials volume. However, a thick nitride layer is commonly desired to reduce the threading dislocation density at the surface of a film structure, as the TD density at the growth surface in general diminishes with the thickness of the nitride layer. On the other hand, after the growth stage it is often desired to make the original foreign substrate thinner or even remove it to form a stand-alone GaN template. However, when thinning the substrate (usually by lapping), the probability of cracking increases. This sets an upper limit for the thickness of the epitaxial GaN layer, and hence a limit to how much the TD density can be reduced by simply growing thicker nitride layers. Let alone that the growth of thick GaN or other nitride layers is expensive.

To avoid the aforementioned negative effects the present invention provides a method and a structure to reduce the level of mechanical stresses at the growth stage of a semiconductor structure, without the formation of a rough surface or cracking of the nitride layers and/or the substrate. A motivation for the present invention is based on the observation on mechanical stress redistribution as a result of patterning a layer. When an initially flat uniformly stressed layer is subjected to the formation of structures with 3D geometry, i.e. islands (or posts), or trenches (or holes), the strain-stress state becomes non-uniform. The top regions of the posts with sufficient height become essentially stress-free and the material between the holes at the top of the layer (the top being the side of the layer which is closer to the growth surface of the structure) also demonstrates the lowered level of the mechanical stresses compared to the stresses of the initial two-dimensional layer having a planar surface. An additional advantage of the relaxation induced by three dimensional patterning of a nitride layer is that the intentional removing of material volumes, contrary to the essentially uncontrolled and chaotic relaxation through cracking, is also able to reduce compressive stresses.

Without limiting the invention to any particular theoretical speculation, change in the stress-strain state gives also rise to shear components of stresses at the bottom of the posts or between the bottoms of the holes. This bottom region may be called e.g. a stress confinement layer, into which stress is confined by the selective removal of material from the first nitride layer. The presence of such shear stresses in the stress confinement layer may be an additional reason for the intensification of the relaxation processes in the patterned structures.

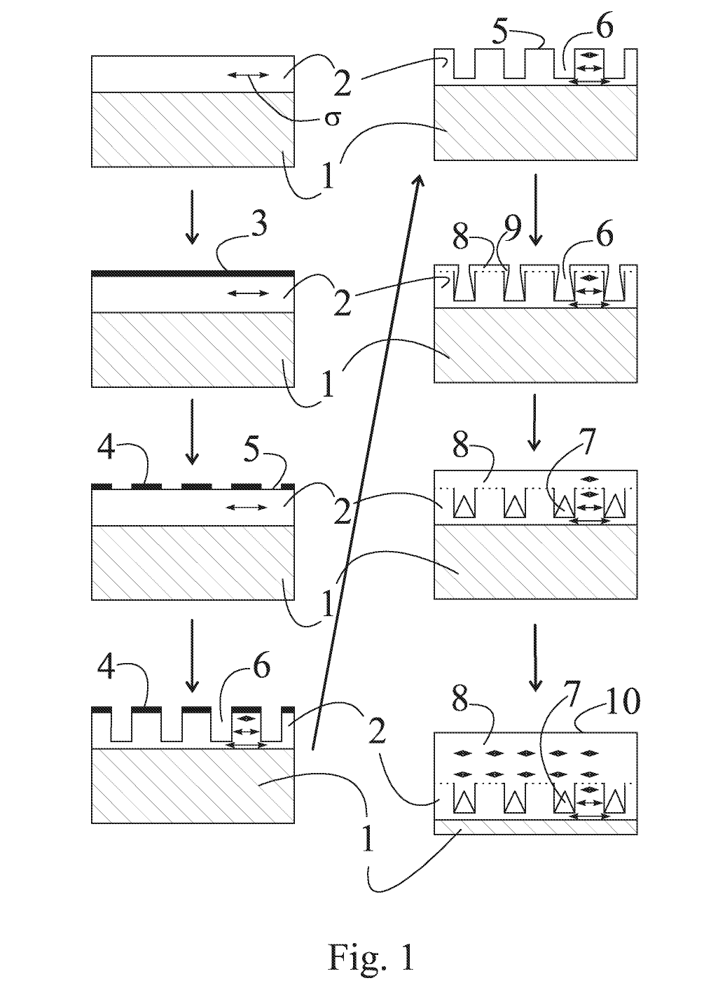

The aforementioned stress redistribution is schematically shown in FIG. 1 illustrating the process flow of a method according to one embodiment of the present invention. The internal mechanical stress a in the lateral direction is presented by the two-directional arrows whose length is proportional to the value of the stress σ, which is tensile in this example, at the indicated location within the structure.

For reasons of simplicity, item numbers will be maintained in the following exemplary embodiments in the case of repeating components.

The process illustrated in FIG. 1 starts by growing, on a sapphire substrate 1, a first nitride layer 2 of e.g. GaN. The step of growing the first nitride layer 2 can be performed by any known procedure to deposit nitride layers from the vapor phase on a (0001) oriented foreign substrate, numerous examples of which having been reported in the literature. For growing this first nitride layer 2 any known process variation of e.g. metalorganic chemical vapor deposition (MOCVD), examples of which are disclosed in the literature, can be used. Resulting mainly from the island coalescence at the early stage of the heteroepitaxial GaN growth, discussed above, this first nitride layer 2 is characterized by high tensile stresses σ at the growth temperature.

In the next step mask material 3 is deposited and a mask 4 defining the desired patterning geometry is formed on the surface 5 of the first nitride layer 2. After patterning the mask material 3 to form the mask 4, volumes of the first nitride layer 2 are removed by etching and hollows 6 are formed in the first nitride layer 2 through the openings in the patterned mask 4. In the step of patterning the first nitride layer 2, standard lithography techniques can be used for fabricating a mask 4 determining the patterning geometry on the surface of the first nitride layer 2. On the other hand, in one embodiment of the invention, the mask needed for the step of patterning the first nitride layer 2 is deposited on the surface of the first nitride layer 2 by nanoimprint lithography.

As a result of the patterning step, and after heating the patterned structure back to a temperature suitable for the nitride growth, the remaining portions of the first nitride layer 2 between the removed volumes, i.e. the hollows 6, are characterized by a relaxed state of tensile stresses σ, as illustrated by the length of the arrows denoting the tensile stress in the nitride. The tensile stress was also found to surprisingly decrease towards the surface 5 (i.e. the surface further away from the substrate 1 interface) of the first nitride layer 2. Hence, as explained above, the removal of volumes from the first nitride layer 2 enables redistribution of internal stresses, which results in a relaxed stress state at, or close to, the remaining surface of the first nitride layer 2. This, as will be described subsequently, can be used to grow a mechanically relaxed second nitride layer 8 over the removed volumes (the hollows 6), without the relaxation occurring in an uncontrolled manner through the generation of cracks.

As a result of the step of patterning the first nitride layer 2, the remaining layer can comprise e.g. separate hollows 6 extending perpendicularly relative to the plane of the layers. The removed volumes can extend even down to the interface between the first nitride layer 2 and the foreign substrate 1. The optimal patterning geometry can vary depending on e.g. the layer thicknesses, on process parameters used in the growth steps, etc. As will be discussed later, excellent results have been obtained by using hollows 6 which have a hexagonal cross-sectional geometry with triangle or square arrangements. For good results the hexagonal hollows 6 should also be made sufficiently big.

After removing the mask 4, growing additional GaN on the remaining portions of the surface 5 of the first nitride layer 2 is started in order to form a second nitride layer 8 of GaN. In the beginning, the process parameters are selected to promote growth in the lateral direction until the laterally grown sections 9 coalesce, fully covering the removed volumes, the hollows 6, of the first nitride layer 2. In this way enclosed voids 7 are formed from the removed volumes within the nitride structure under the second nitride layer 8. Important is the achievement of a good contact of coalescing surfaces of the second nitride layer 8 at the end of the lateral growth stage. “A good contact” in this case means that the region around the boundary of two coalesced laterally grown sections 9, i.e. the contact zone, has a minimum amount of defects, including threading dislocations. The actual process parameters needed in said growth control depend even on individual process equipment, thus no generic detailed parameters can be given. However, a person skilled in the art can find suitable parameters through routine testing.

In order to achieve lateral growth over the hollows 6, the relative growth rate of different crystallographic planes of GaN having a wurtzite crystalline structure is adjusted by a suitable choice of process parameters. The suitable process parameters for lateral growth in the commonly used MOCVD growth (crystal growth parameters) of wurtzite GaN result in a relatively low growth rate for the (0001) plane. The key process parameters to be selected in order to achieve the lateral growth are the growth temperature and the III/V ratio. Process parameters enabling lateral growth of GaN are readily available from the public literature and can be easily selected and optimized by the skilled professional in light of this disclosure. After the removed volumes, the hollows 6, of the first nitride layer 2 are fully covered, the growth mode is changed to prefer vertical growth in the (0001) direction. Again, this type of control of the growth direction of GaN is readily achieved by the skilled professional.

Growing the second nitride layer 8 in the vertical (0001) direction is continued until a desired total thickness for the layer is achieved. This desired total thickness can depend on various things which include e.g. mechanical strength of the whole structure and the targeted TD density of the top of the layer. The additional GaN of the second nitride layer 8 surprisingly grows with essentially the same relaxed stress state of those locations of the first nitride layer 2 from which the growth of the second nitride layer 8 was started. These locations are at the top part of the portions between the removed volumes of the first nitride layer 2. In addition to preventing cracking of the template, of the foreign substrate, and of the possible device layers grown on the second nitride layer 8, the low mechanical stress state also enables producing a template surface 10 having a very smooth surface morphology, i.e. a very low surface roughness.

As the last step of the process of FIG. 1, the original sapphire substrate 1 is thinned by lapping. The final outcome of the process is a III-nitride template characterized by a very small surface roughness, a highly relaxed stress state and a low TD density at the surface 10. Such a template serves as an excellent substrate for subsequent deposition of device layers of e.g. a high brightness LED.

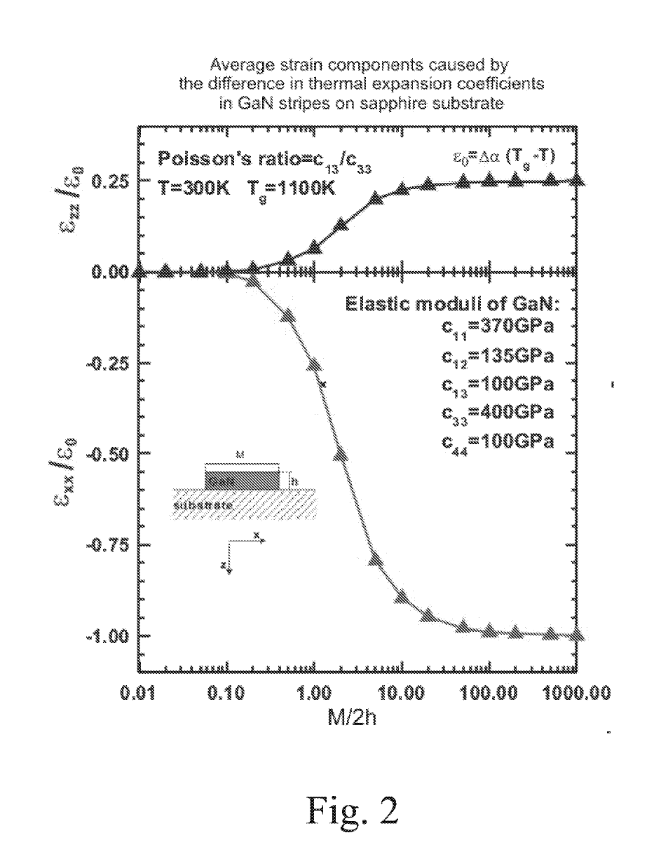

Stress and elastic strain components in a GaN deposit with a (0001) oriented surface on a sapphire substrate were also theoretically modeled by analytical and finite element (FEM) calculation in cases of tensile growth stresses or compressive stresses of thermal origin. The results of these calculations are shown in FIG. 2 which clearly shows that the stress/strain state in the GaN deposit on a sapphire substrate strongly depends on the geometrical dimensions, e.g. on the shape, of the GaN deposit. FIG. 2 shows the results of a theoretical calculation presenting the effect of the aspect ratio M/2h of posts formed by selectively etching away portions of the first nitride layer 2 grown on sapphire substrate and subjected to cooling from growth temperature to room temperature.

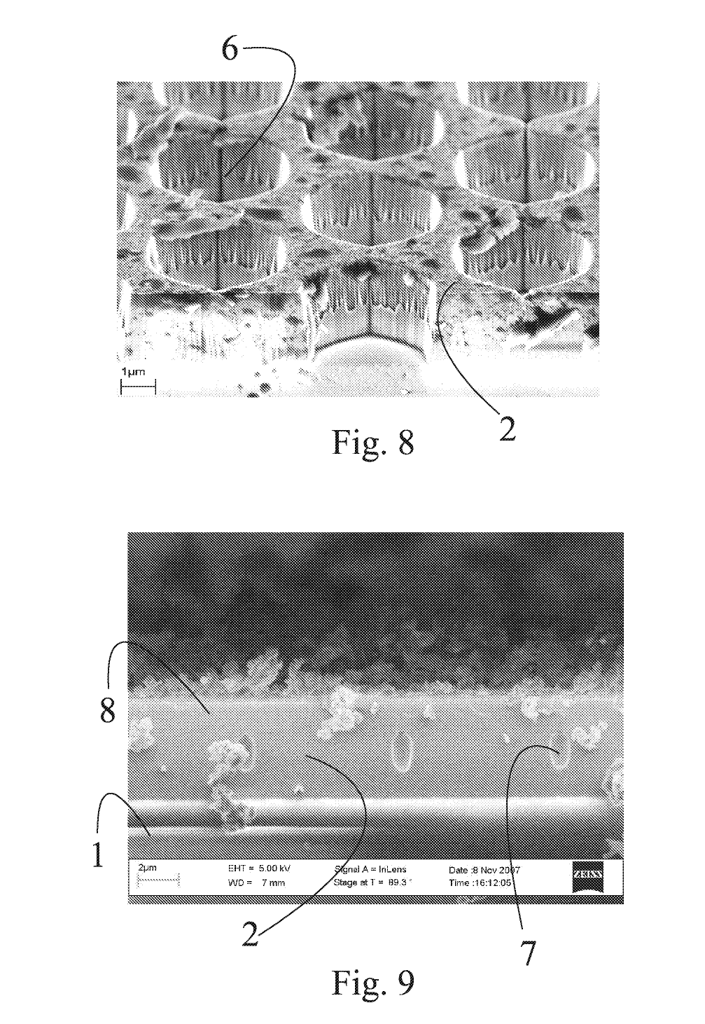

As already indicated above, the shape of the removed volumes, the hollows 6, play a role in achieving a desired stress relaxation effect which surprisingly also enables the growth of the relatively relaxed second nitride layer with a smooth surface morphology. In one embodiment of the invention the removed volumes are hexagon shaped (see e.g. the SEM image of FIG. 8). This geometry for the removed volumes provides a necessary crystal geometry for the growth process of the second nitride layer 8 and efficiently relaxes stresses in the remaining top regions of the first nitride layer 2, and hence a relatively stress free second nitride layer 8 could be grown. The stresses were very efficiently relaxed in the second nitride layer 8 and correspondingly also in the remaining top regions of the first nitride layer 2 when additionally characteristic cross-sectional diameter of the hollows 6 was more than 2.0 micrometers, the spacing between adjacent hollows 6 in the etched pattern of the first nitride layer 2 was less than 6.0 micrometers while the depth of the etched hollows was more than 3.0 micrometers.

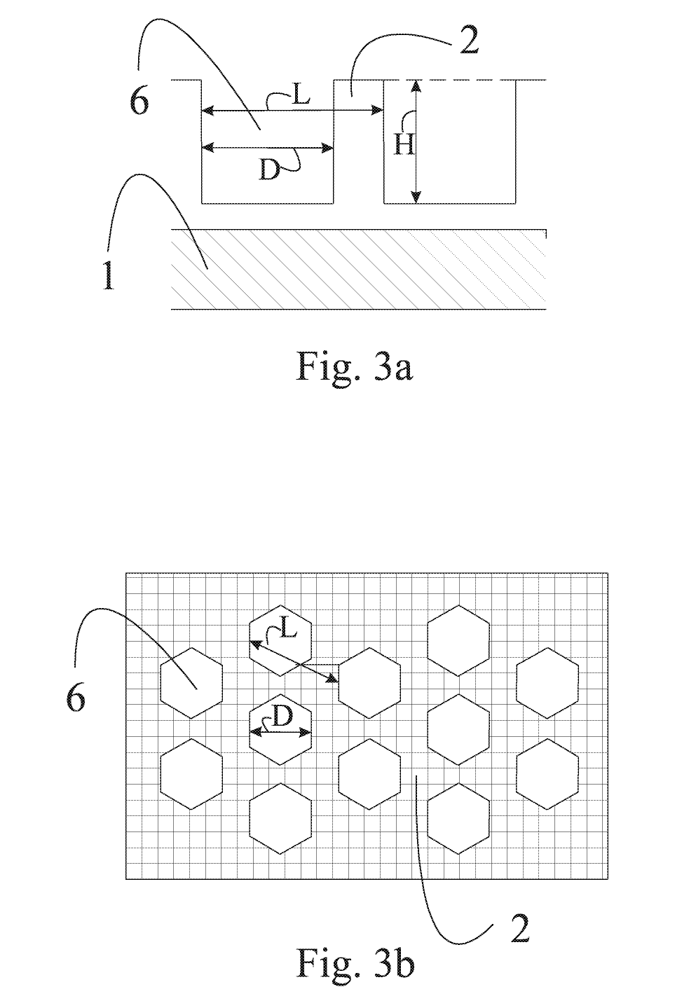

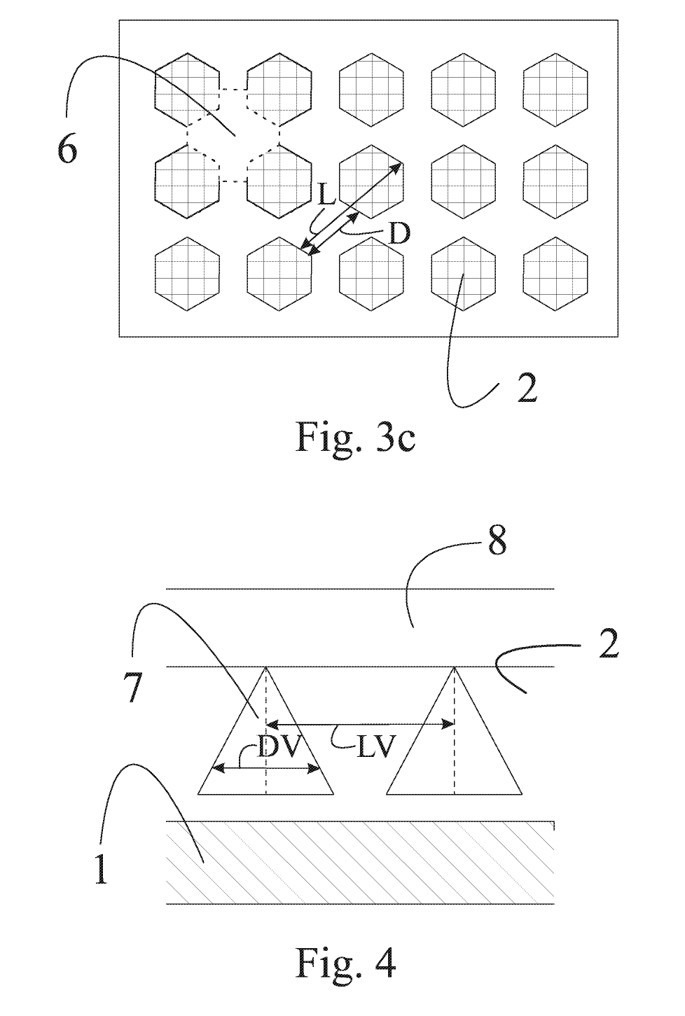

The height H of the hollows 6 depending on the depth of etching of the first nitride layer 2, the characteristic diameter D of the hollows 6, and the spacing L between adjacent hollows 6 are the three structural parameters which most affect the mechanical internal stress state of the second nitride layer 8 which will be grown over the hollows 6 as described above. Definitions for the three parameters H, L and D are schematically illustrated in FIG. 3a, FIG. 3b and FIG. 3c. For very efficient stress relaxation the ratio of the height H to the width of the regions of remaining material in between the hollows 6, defined by L-D, satisfy the condition H/(L−D)>0.5. Under this condition majority of the material in the region of remaining material in between the hollows 6 will be relaxed (this can be inferred from e.g. FIG. 1 and FIG. 2), and correspondingly the mechanical internal stresses of the overgrown second nitride layer 8 will be very efficiently relaxed.

In FIG. 3b the hollows 6 are hexagonal pits that form a triangular pattern in the first nitride layer 2 and the hollows 6 are confined in all lateral directions, i.e. in all directions in the plane of the layers, by the remaining regions of the first nitride layer 2 from which material has not been removed by e.g. etching. As illustrated in FIG. 3c the hollows 6, that in this case form a square pattern, are not necessarily confined in all lateral directions but the hollows 6 can alternatively be continuous regions extending throughout the plane of the first nitride layer, and the remaining “unetched” regions of the first nitride layer 2 are in this embodiment surrounded by the hollows 6. I.e. in FIG. 3c the remaining regions of the first nitride layer 2 in between the hollows 6 are posts with, in this case, a lateral cross section shaped as a hexagon.

As the periodic pattern of the three dimensional removed volumes, the hollows 6, formed in the first nitride layer 2 may vary, as described above, the characteristic diameter D, the spacing L, and the height H of the hollows 6 defined above should be understood in this specification as parameters which are averaged over one region defining a hollow 6. In the case of a hollow 6 which is bounded by the first nitride layer 2 in all lateral directions (see FIG. 3b), this boundary should be used to define the region of the hollow 6. In some patterning geometries in which the hollow 6 is not confined in all lateral directions (see FIG. 3c) by the first nitride layer 2 to a discrete location, the three parameters (D, L and H) should be understood as averages over a region of a hollow 6 whose boundaries in the lateral direction are defined by the boundaries of the laterally adjacent regions of the first nitride layer 2 and straight lines connecting the midpoints of these adjacent regions of the first nitride layer 2 (see the dashed line in FIG. 3c). The arrows in FIG. 3a, FIG. 3b and FIG. 3c are for illustrative purposes only and they are not intended to represent the actual averages for the parameters D, L or H.

Similarly to the definition of D, L, and H, FIG. 4 schematically presents a characteristic diameter DV and the lateral spacing LV between adjacent voids 7 which are intentionally induced to the structure by overgrowing the hollows 6 of the first nitride layer 2 by the second nitride layer 8. The parameters DV and LV are also averaged parameters whose values are calculated over a cross-section of the voids along a surface parallel to the surface of the foreign substrate 1.

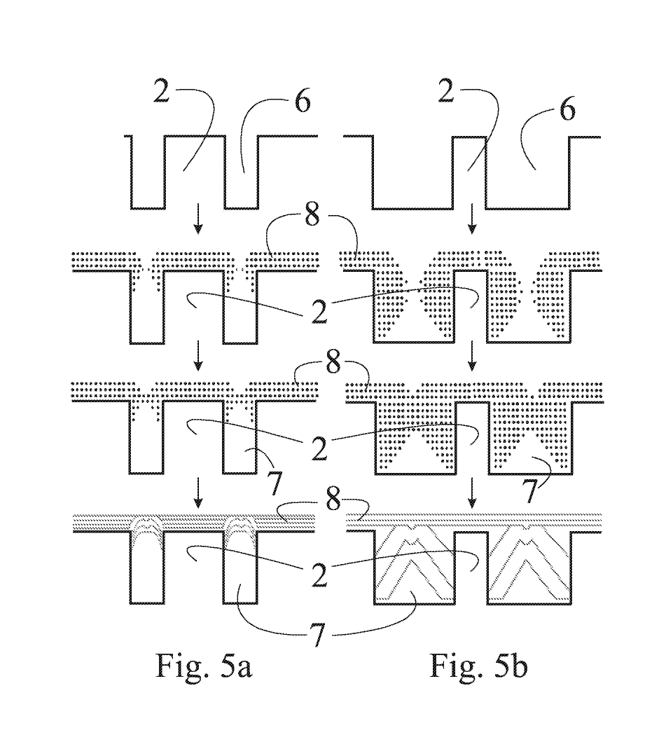

Without limiting the invention to any particular growth model we propose a probable model that describes the growth mechanism of the second nitride layer 8 accounting for the observed advantages of stress relaxation, and reduction of the TD density. The critical parameter of the growth model, explained below with references to FIG. 5a and FIG. 5b, is the sidewall angle of the hollow 6 and the resulting enclosed voids 7 in samples with different sizes and shapes of hexagon-shaped hollows 6. The growth conditions in this model are optimized to favor lateral growth of the GaN second nitride layer 8.

FIG. 5a illustrates the process flow for the case where the hollows 6 have a small diameter in the plane parallel to the films. As there is only a narrow opening for the growth to take place, there is a large difference in the supply of the reactive species at the top of the sidewalls as compared to the bottom of the hole due to the limited diffusivity of the reactive species, e.g. gaseous trimethylgallium or ammonia in the case of MOCVD growth. This favors the growth of the second nitride layer on the top most area of the hollows 6 both vertically and sideways. As the structure continues to grow thicker the opening starts getting smaller from the top. Hence it becomes more and more difficult for the precursor atoms to reach down to the bottom of the etched hollow 6. This results in negligible growth on the side walls.

In the case of hollows 6 with a larger diameter, illustrated in FIG. 5b, it is possible that there is more chance for the reactive species to stick to the sidewalls close to the bottom of the hollow 6, and that there is a local gradient of the concentration of the reactive species along the sidewalls inside the hollows 6. This may also cause a gradient in the V/III-ratio in an MOCVD GaN process utilizing trimethylgallium and ammonia. The large enough size of the hollows 6 is necessary for and allows for the formation of this gradient. Such a gradient results in the formation of inclined sidewalls during the growth of the second nitride layer 8. Again without limiting the invention by any theoretical speculation, this inclined sidewall profile may stimulate the inclination of TDs and the relaxed growth of the second nitride layer 8, although the exact mechanism leading to these surprising advantages is not entirely understood at this point.

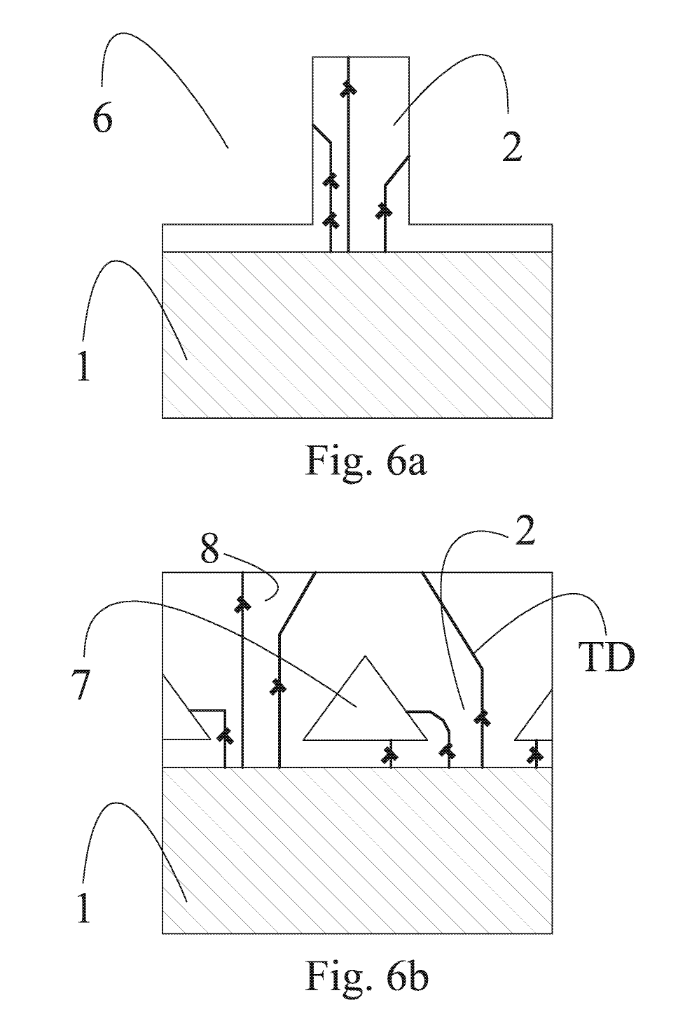

Indeed, in addition to the stress state, the etched hollows 6 also affect the threading dislocation density in the nitride layers. It has been found that the threading dislocation density in the top areas of the second nitride layer 8 can be drastically lower than that observed in the first nitride layer 2 before patterning. The possible mechanisms of threading dislocation density reduction are (i) interaction of TDs with lateral post surfaces and exit of TDs on these surfaces; (ii) interaction of TDs with free surfaces of the hollows 6 with exit or change of TD line trajectory, the latter case resulting in a TD becoming inclined and thus gaining a higher probability for reactions with other dislocations during the subsequent growth of the second nitride layer 8. These effects are schematically shown in FIG. 6a and FIG. 6b.

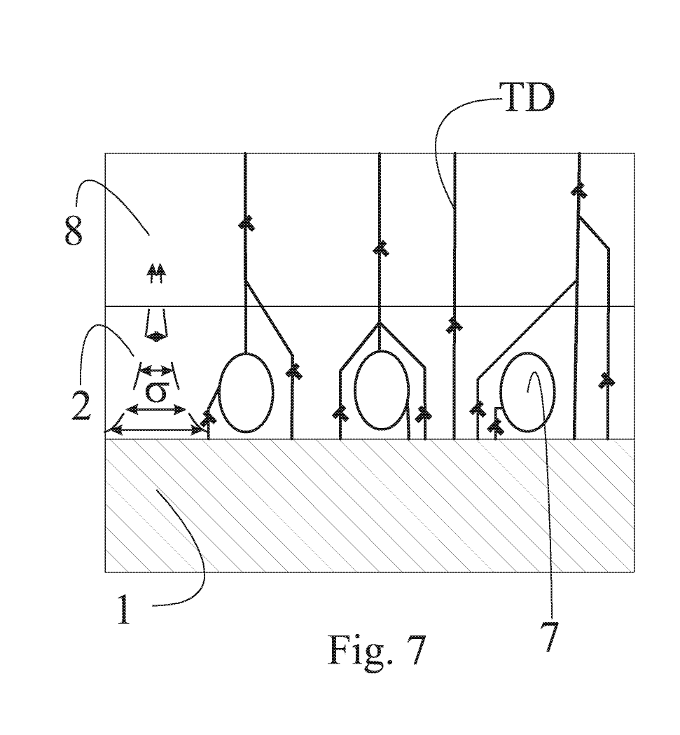

The initial density of the threading dislocations in the nitride layers is decreased due to termination of some of the dislocations at the boundaries of the etched volumes. Further, part of the remaining threading dislocations change their initially substantially vertical line trajectories to inclined ones due an interaction with the hollows 6. During the growth of the second nitride layer 8, these inclined dislocations have an increased probability to meet and react with each other, thereby reducing the total number of threading dislocations at the top portions of the finalized semiconductor structure. FIG. 7 illustrates the effect of the enclosed voids 7 formed within the first nitride layer 2 on the propagation of TDs in the semiconductor structure. Due to an interaction with the voids 7, some TDs become inclined and some of them terminate at the boundaries of the voids 7. Inclination significantly increases the probability of the dislocations to interact and react with each other during further growth. As a result of such reactions annihilation of two dislocations with opposite Burgers vectors or fusion of two dislocations to produce a single TD may take place. Both these processes decrease the total number of TDs and thus the TD density. In contrast to e.g. epitaxial lateral overgrowth or pendeoepitaxy techniques providing threading dislocation density reduction above specific areas only, in this process the TD density is reduced throughout the template area. A schematic illustrating both, the effect of stress reduction and TD density reduction towards the top surface of a semiconductor structure according to one embodiment of the present invention is presented in FIG. 7.

Experimental results illustrating the technical effects of the embodiments of the invention discussed above are presented in FIG. 8 to FIG. 10, which display scanning electron microscope (SEM) images of nitride semiconductor structures according to some embodiments of the present invention.

FIG. 8 presents an SEM image of hexagon shaped removed volumes, hollows 6, of the first nitride layer 2 after patterning according to one embodiment of the present invention. A characteristic diameter D of these hexagons is about 4.5 micrometers and the spacing L between adjacent hexagons is about 5.5 micrometers.

The SEM image of FIG. 9 shows the cross section of a GaN template grown on a (0001) oriented sapphire substrate 1. Enclosed voids 7 are formed within the template. Thanks to the relaxed stress state of the nitride in the upper portions of the template, the upper surface 10 of the template has an excellent surface morphology (the debris on the sample resulting from sample preparation should not be interpreted as part of the semiconductor structure).

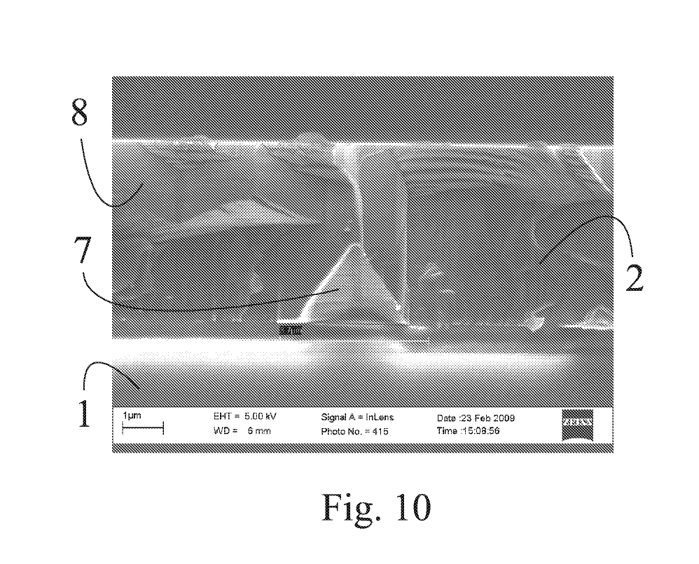

The SEM image of FIG. 10 presents the patterned first nitride layer 2 of FIG. 8 which has been overgrown by a second nitride layer 8 according to one embodiment of the present invention. Notice the inclined sidewalls of the enclosed void 7 in FIG. 10.

Note also that cross sections shown in FIG. 9 and FIG. 10 do not necessary demonstrate the shortest distance between the voids 7.

### EXAMPLES

C-plane sapphire substrates 1 were used to grow GaN films in a vertical flow 3×2″ close coupled showerhead (CCS) MOCVD reactor. A low temperature nucleation layer followed by a 3.2 μm un-doped GaN layer grown at an elevated temperature (1030° C.) was used to grow the first nitride layer 2 of GaN on the substrate 1. The growth process for this first nitride layer 2 is a conventional MOCVD GaN process which will be obvious for a skilled person. TMG (trimethylgallium) and ammonia (NH3) were used as the source gases while hydrogen ambient was used to perform the growth of GaN. The reactor pressure was kept at 200 torr during the growth of the first nitride layer 2. The conventional photolithographic method was used to create hexagonal shaped patterns on the underlying first nitride layer 2. An e-beam system was used to evaporate Ni onto the first nitride layer 2 covered with patterned photo resist. This was consequently followed by the lift-off process in an ultrasonic bath. The next step in the process was to etch the first nitride layer 2 of GaN through the Ni mask 4 openings. This was performed in an inductively coupled plasma (ICP) chamber. The etching conditions were 15 sccm of Cl₂, 2.5 sccm of Ar with a total pressure of 4 mtorr. The RF power was kept at 150 while 450 W of ICP power was used during the etching process. After the etching of GaN, a mixture of HCl:HNO₃ (3:1) was used to removed the Ni mask 4 from the top of the first nitride layer 2. A standard cleaning procedure was adopted to clean the structure's surface before placing the wafer back into the MOCVD reactor. The samples were cleaned with acetone, 2-propanol, H₂SO₄:H₂O₂ (4:1) mixture, buffered hydrofluoric acid (BHF) and de-ionized water (DIW).

The next step involved the growth of a second nitride layer 8 of GaN on the samples prepared by the method as described above. Same precursor materials and ambient atmosphere were used for the growth of the second nitride layer 8 of GaN. During this growth process various reactor parameters such as temperature, V/III ratio and pressure were varied, as described above, in order to obtain the desired lateral or vertical growth mode. The growth process for this second nitride layer 8 is a conventional MOCVD GaN process which will be obvious for a skilled person.

Scanning electron microscopy (SEM) was used to make an in-depth analysis of the etched structures and the subsequent formation of voids 7 after the regrowth (i.e. the growth of the second nitride layer 8). These SEM images are presented in FIG. 8 to FIG. 10.

In addition to SEM images from the grown samples X-ray diffraction (XRD) was also employed to quantitatively evaluate the effect the invention has on the stress state of a nitride layer on a foreign substrate 1. The XRD results showed narrower diffraction peaks for a GaN semiconductor structure according to an embodiment of the present invention on a sapphire substrate 1 compared to a GaN layer with a similar thickness and TD density on a sapphire substrate 1. The FWHM peak widths for the inventive structure were 320.4 arcsec and 291.6 arcsec for a (302) and for a (102) asymmetric ω scan, respectively. The FWHM peak widths for the GaN layer of the prior art were 414 arcsec and 381 arcsec for a (302) and for a (102) asymmetric ω scan, respectively. The surprisingly narrower peaks in the case of the inventive structure could be attributed to stress relaxation achieved via patterning the first nitride layer 2 and laterally growing the second nitride layer 8 over the removed volumes of the first nitride layer 2.

It is obvious for a person skilled in the art that the basic idea of the invention may be implemented in various ways. As is clear for a person skilled in the art, the invention is not limited to the examples described above but the embodiments can freely vary within the scope of the claims.

1. A method for reducing internal mechanical stresses in a semiconductor structure formed of nitrides of group III metals on a (0001) oriented foreign substrate (1), characterized in that the method comprises the steps of
growing nitride on the foreign substrate (1) to form a first nitride layer (2),
patterning the first nitride layer (2) by selectively removing volumes of it to a predetermined depth from the upper surface (5) of the first nitride layer (2), for providing relaxation of internal mechanical stress in the remaining portions of the layer between the removed volumes, and
growing, on the first nitride layer (2), starting on the remaining portions of the upper surface (5) of the first nitride layer (2), additional nitride until a continuous second nitride layer (8) is formed, to produce enclosed voids (7) from the removed volumes under the second nitride layer (8) inside the semiconductor structure, said growing comprising growing the additional nitride such that the growth rate decreases gradually towards the bottom of the removed volumes, for enclosing the voids (7) from the removed volumes such that the characteristic cross-sectional diameter of the voids (7), along a surface parallel to the surface of the foreign substrate (1), increases as a function of depth.

2. The method of claim 1, characterized in that patterning the first nitride layer (2) comprises removing volumes of the first nitride layer (2), such that the depth H of the removed volumes, a characteristic diameter D of a cross-section of the removed volumes along a surface parallel to the surface of the foreign substrate (1), and the spacing L between adjacent removed volumes satisfy the condition H/(L−D)>0.2, more preferably the condition H/(L−D)>0.4, and most preferably the condition H/(L−D)>0.6.

3. The method of claim 1, characterized in that patterning the first nitride layer (2) comprises removing volumes of the first nitride layer (2) such that the cross-section of the removed volumes, along a surface parallel to the surface of the foreign substrate (1), is shaped as a hexagon.

4. The method of claim 1, characterized in that orientation of the faces of the removed volumes essentially coincide with the low index crystallographic planes of a wurtzite crystal structure.

5. The method of claim 1, characterized in that the cross-section of the removed volumes, along a surface parallel to the surface of the foreign substrate (1), has a characteristic diameter D of at least 2.0 micrometers, the spacing L between adjacent removed volumes is less than 10.0 micrometers, and the depth H of the removed volumes is more than 3.0 micrometers.

6. (canceled)

7. A semiconductor structure with low mechanical stresses, formed of nitrides of group III metals on a (0001) oriented foreign substrate (1), characterized in that the structure comprises a first nitride layer (2) on the foreign substrate (1), a second nitride layer (8) on the first nitride layer (2), the second nitride layer (8) enclosing intentionally induced voids (7) under the second nitride layer (8) inside the semiconductor structure, for reducing internal mechanical stresses in the semiconductor structure, the characteristic cross-sectional diameter of the voids (7), along a surface parallel to the surface of the foreign substrate (1), increasing as a function of depth, the voids having been obtained by patterning the first nitride layer (2) by selectively removing volumes of it to a predetermined depth from the upper surface (5) of the first nitride layer (2), and growing, on the first nitride layer (2), starting on the remaining portions of the upper surface (5) of the first nitride layer (2), additional nitride until a continuous second nitride layer (8) is formed, to produce enclosed voids (7) from the removed volumes under the second nitride layer (8) inside the semiconductor structure.

8. The structure of claim 7, characterized in that the cross-section of the voids (7), along a surface parallel to the surface of the foreign substrate (1), has a characteristic diameter DV of at least 2.0 micrometers, and the lateral spacing LV between adjacent voids (7) is less than 10.0 micrometers.

9. (canceled)

10. Use of the method of claim 1 to reduce internal mechanical stresses in a semiconductor structure formed of nitrides of group III metals.

11. Use of the structure of claim 7 to reduce internal mechanical stresses in a semiconductor structure formed of nitrides of group III metals.

12. The method of claim 2, characterized in that patterning the first nitride layer (2) comprises removing volumes of the first nitride layer (2) such that the cross-section of the removed volumes, along a surface parallel to the surface of the foreign substrate (1), is shaped as a hexagon.

13. The method of claim 12, characterized in that orientation of the faces of the removed volumes essentially coincide with the low index crystallographic planes of a wurtzite crystal structure.

14. The method of claim 13, characterized in that the cross-section of the removed volumes, along a surface parallel to the surface of the foreign substrate (1), has a characteristic diameter D of at least 2.0 micrometers, the spacing L between adjacent removed volumes is less than 10.0 micrometers, and the depth H of the removed volumes is more than 3.0 micrometers.
